(19) United States
(12) Patent Application Publication
(10) Pub. No.: US 2008/0191347 A1
(43) Pub. Date: Aug. 14, 2008

(54) CONDUCTIVE BALL-OR PIN-MOUNTED SEMICONDUCTOR PACKAGING SUBSTRATE, METHOD FOR MANUFACTURING THE SAME AND CONDUCTIVE BONDING MATERIAL

(76) Inventors: Kazunori Sawa, Iruma-shi (JP); Shinichi Akaike, Iruma-shi (JP)

Correspondence Address: KING & SCHICKLI, PLLC, 247 NORTH BROADWAY, LEXINGTON, KY, 40507, US

(21) Appl. No.: 12/020,659

(22) Filed: Jan. 28, 2008

(30) Foreign Application Priority Data
Jan. 31, 2007 (JP) 2007-47953

(51) Int. Cl. H01L 23/498; C22C 18/00; H01L 21/768

(52) U.S. Cl. 257/737; 420/513; 438/613; 257/E23.068; 257/E21.589

(57) ABSTRACT

There is disclosed a conductive ball- or pin-mounted semiconductor packaging substrate having a conductive ball or a conductive pin mounted on a conductive land or through-hole of the semiconductor packaging substrate, wherein the conductive ball or the conductive pin is electrically connected with the conductive land or through-hole through a reflow of a conductive bonding material comprising, at least, a low-melting point lead-free SnBi-based solder and a thermosetting adhesive resin exhibiting fluxing effects.

This application claims priority from Japanese Patent Application No. 2007-47953 filed on Jan. 31, 2007.

### TECHNICAL FIELD

This invention relates to a conductive ball-mounted or pin-mounted semiconductor packaging substrate, to a method of manufacturing the conductive ball- or pin-mounted semiconductor packaging substrate and to a conductive bonding material useful for this manufacturing method. In particular, this invention relates to a semiconductor packaging substrate (such as a ball grid array (BGA) and a pin grid array (PGA)) with a conductive ball or a conductive pin being electrically connected thereto through a conductive land or a through-hole.

### BACKGROUND OF THE INVENTION

Due to the recent trend to miniaturize electronic instruments or to reduce wall-thickness of electronic instruments, there has been conventionally practiced to package modularized electronic components, to assemble semiconductor elements such as IC and LSI as well as various kinds of electronic components, and to mount these electronic components on a printed wiring board (PWB).

For example, in the case of the BGA, as shown in FIG. 1, a semiconductor chip 6 is connected through a bump 5 to a circuit wiring 1a formed on one surface of a circuit board 1 and a circuit wiring 1b formed on the other surface of the circuit board 1 is provided with a solder ball, thereby forming a bump 7. The circuit board mounted with a semiconductor chip as described above is connectively mounted, through the fusion of the bump 7, on a mother board (not shown).

As for the method of forming the bump 7 on a circuit board mounted with a semiconductor substrate as described above, i.e. as for the method for forming the external terminals of ordinary semiconductor package substrate, there are known various methods including (i) a method wherein a solder paste or flux is applied to a conductive land of semiconductor package substrate and then a solder ball to be fused by way of reflow (240° C.) is mounted on the solder paste or flux; and methods which are designed to prevent the falling of the solder ball before the step of reflow or to improve the bonding strength after the reflow, such methods including (ii) a method of forming an underfill (JP-A 2000-349185 (KOKAI)); (iii) a method of forming an adhesive layer for the solder ball (JP-A 2000-277666 (KOKAI)); and (iv) a method of applying a special recess-forming work to the vicinity of a portion where the solder ball is to be mounted (JP-A 2006-54494 (KOKAI))

However, the method (i) is accompanied with a problem that the solder ball may fall away before the reflow thereof from the place where the solder ball has been mounted. Especially in the recent trend to further increase the mounting density of electronic components onto a substrate, thus narrowing the pitches between lands where the solder ball is to be mounted and decreasing the contacting area between the land and the solder ball, there is increasing possibilities to cause the solder ball to fall away from the substrate. Even if it is possible to prevent the falling of the solder ball, it requires troublesome washing of residual flux after the reflow.

On the other hand, the methods of (ii) to (iv) are also accompanied with problems that they require additional processes for forming an underfill or adhesive layer or executing the work for forming a special recessed portion, Especially, in the method (iii) for forming the adhesive layer, it requires pressures, thereby occasionally imposing an excessive stress to the parts such as semiconductor elements or to a circuit board.

### BRIEF SUMMARY OF THE INVENTION

The present invention has been accomplished in view of the aforementioned circumstances and hence one object of the present invention is to provide a conductive ball- or pin-mounted semiconductor packaging substrate which not only makes it possible to electrically connect a conductive ball or a conductive pin with a conductive land or through-hole of the semiconductor packaging substrate at low temperatures but also makes it possible to concurrently achieve the improvement of conductivity of connection of circuit that can be achieved by means of soldering and the adhesive strength of the conductive ball or the conductive pin that can be achieved by making use of an adhesive. Another object of the present invention is to provide a method of manufacturing such a conductive ball-mounted semiconductor packaging substrate. A further object of the present invention is to provide a conductive bonding material which is useful for the aforementioned manufacturing method.

By the way, by the term “conductive ball”, it is intended to include not only a conductive ball in strict sense, but also any kinds of similar configurations thereto such as a conductive pin and the like unless specified otherwise.

As a result of extensive studies made by the present inventors in an attempt to achieve the aforementioned objects, it has been found out that these objects can be achieved by making use of mainly a curable component as a resin component to thereby obviate any influence that may be brought about by the employment of uncured component and by making use of an SnBi-based solder having a melting point of 130-170° C. to thereby enable the solder to fuse prior to the curing of the resin component, thus accomplishing the aforementioned objects.

Accordingly, the present invention provides (1) a conductive ball- or pin-mounted semiconductor packaging substrate having a conductive ball or a conductive pin mounted on a conductive land or through-hole of the semiconductor packaging substrate, wherein the conductive ball or the conductive pin is electrically connected with the conductive land or through-hole through the coating and reflow of a conductive bonding material comprising, at least, a conductive material formed of a low-melting point lead-free solder having a melting point of 130-170° C., and a thermosetting adhesive resin exhibiting fluxing effects.

Further, the present invention also provides (2) the conductive ball- or pin-mounted semiconductor packaging substrate as described in the above item (1), wherein the low-melting point lead-free solder is formed of a SnBi-based solder, and the thermosetting adhesive resin exhibiting fluxing effects is constituted by a mixture comprising an epoxy resin and a curing agent.

The present invention further provides (3) the conductive bonding material set forth in the above items (1) or (2).

The present invention further provides (4) a method of manufacturing the conductive ball- or pin-mounted semiconductor packaging substrate having a conductive ball or a conductive pin mounted on a conductive land or through-hole of the semiconductor packaging substrate, the method comprising the steps of: forming a conductive bonding material layer by applying a conductive bonding material comprising, at least, a low-melting point lead-free SnBi-based solder and a thermosetting adhesive resin exhibiting fluxing effects to the conductive land or through-hole; and causing the conductive bonding material to reflow to thereby electrically connect the conductive ball or the conductive pin with the conductive land or through-hole.

In the present invention, by the expression of: “exhibiting fluxing effects” which is mentioned in connection with the conductive bonding material, it is intended to mean phenomena that, as in the case of the ordinary rosin-based flux, a coated film thereof formed to cover the metallic surface of soldered body so as to intercept air atmosphere is enabled, due to an active component thereof, to reduce the metal oxide on the metallic surface on the occasion of soldering and, at the same time, the coated film is pushed away by the fused solder, thereby permitting the fused solder to contact with the metallic surface while enabling the residue of the coated film to act as an insulating material between the circuit elements.

As for the major component of the thermosetting type adhesive resin provided with the aforementioned fluxing effects, it is possible to employ epoxy resin, phenol resin, polyimide resin, polyurethane resin, melamine resin and urea resin. A resin selected from the group consisting of these resins should preferably be employed singly or as a mixture of two kinds thereof. Further, it is preferable to select those which are liquid at normal temperatures. If a solid resin is to be employed, the solid resin should preferably be used in combination with one which is liquid at normal temperatures.

As for the epoxy resin, it is possible to employ those which are known in the art, specific examples thereof including, for example, bisphenol A, bisphenol F, biphenyl type resin, naphthalene type resin, cresol novolak type resin, and phenol novolak type resin. A resin selected from the group consisting of these resins should preferably be employed singly or as a mixture of two kinds thereof. Further, it is preferable to select those which are liquid at normal temperatures. If a solid resin is to be employed, the solid resin should preferably be used in combination with one which is liquid at normal temperatures.

In order to enhance the fluxing effects in the present invention, it may be advisable to employ an organic acid, preferably a dibasic acid having alkyl group on its side chain. As for the kind of this dibasic acid, although there is not any particular limitation, it is preferable to employ those having not less than six carbon atoms (dibasic acid having at least six carbon atoms). As for the alkyl group to be employed for constituting the side chain, it is preferable to employ lower alkyl group having 1 to 5 carbon atoms. As for the number of alkyl group to be employed for constituting the side chain, it may be only one or two or more. If a plurality of alkyl groups are included in the molecule of the organic acid, these alkyl groups may be the same with or different from each other. For example, it is possible to employ linear or branched lower alkyl group having 1 to 5 carbon atoms, specific examples thereof including methyl, ethyl, propyl, isopropyl, butyl, isobutyl, sec-butyl, tert-butyl, pentyl, isopentyl, neopentyl, tert-pentyl, etc. As for specific examples of the dibasic acid having alkyl group on its side chain, they include gultaric acid having alkyl group (lower alkyl group) on its side chain such as 2,4-diethylgultaric acid, 2,2-diethylgultaric acid, 3-methylgultaric acid, 2-ethyl-3-propylgultaric acid, etc. Other than these preferable dibasic acids, it is also possible to employ 2,5-diethyladipic acid (adipic acid having ethyl groups on its two sites) as well as adipic acid having alkyl group (lower alkyl group) on its side chain.

The employment of a dibasic acid having alkyl group on its side chain is advantageous in that it can be readily dissolved in epoxy resin or in a mixture consisting of epoxy resin and a curing agent (both may be referred hereinafter to resinous material), so that the deposition of the crystal thereof would hardly take place during the storage of the bonding material. Therefore, since this dibasic acid is enabled to diffuse uniformly into the resinous material, the insulation reliability of the film of resinous material can be hardly deteriorated as the resinous material is cured. The dibasic acid having alkyl group on its side chain, especially 2,4-diethylgultaric acid and 2,5-diethyladipic acid should preferably be mixed into epoxy resin or resinous material (a dibasic acid having alkyl group on its side chain/(epoxy resin+a dibasic acid having alkyl group on its side chain) or a dibasic acid having alkyl group on its side chain/(epoxy resin+a curing agent+a dibasic acid having alkyl group on its side chain)) at a concentration of 1 to 10 wt %. When the mixing ratio of dibasic acid having alkyl group on its side chain, especially 2,4-diethylgultaric acid and 2,5-diethyladipic acid, is 1 wt % or more, it is possible to provide the epoxy resin and the resinous material with excellent solderability and to easily secure the wettability of the epoxy resin and the resinous material to semiconductor chips and the like. On the other hand, when the mixing ratio of dibasic acid having alkyl group on its side chain is confined to not more than 10 wt %, it is possible to provide the film of cured resinous material with excellent insulation reliability. Furthermore, it is also possible to employ, as an auxiliary active agent, a little amount of succinic acid, malonic acid, gultaric acid, adipic acid, suberic acid, azelaic acid, sebacic acid, etc.

In the case of the conductive bonding material according to the present invention, a cure-accelerating agent may be employed (although it may be employed as an auxiliary curing agent together with a curing agent, it can be also employed independently, so that it may be considered as a sort of curing agent). This cure-accelerating agent is designed to be employed for accelerating the curing of epoxy resin. For example, it is possible to employ, as a potential cure-accelerating agent, Novacure HX-3722, HX-3721, HX-3748, HX-3088, HX-3613, HX-3921HP, HX-3941HP (all trade name; Asahi Kasei Epoxy Co., Ltd.), to employ, as an aliphatic polyamine-based cure-accelerating agent, Fujicure FXR-1020, FXR-1030, FXR-1050, FXR-1080, (all trade name; Fuji Kasei Industries Co., Ltd.), to employ, as an epoxy resin amine adduct-based cure-accelerating agent, Amicure PN-23, MY-24, VDH, UDH, PN-31, PN-40 (all trade name; Ajinomoto Fine Techno Co., Ltd.), and EH-3615S, EH-3293S, EH-3366S, EH-3842, EH-3670S, EH-3636AS (all trade name; Asahi Denka Industries Co., Ltd.). Further, it is possible to employ, as an imidazole-based cure-accelerating agent, 2MZA, 2PZ, C11Z, C17Z, 2E4MZ, 2P4MZ, C11Z-CNS, 2PZ-CNZ (all trade name).

As for specific examples of low melting point lead-f-ee solder material to be employed in the present invention, it is also preferable to employ the SnBi-based solder or those having a melting point (a state wherein a liquid phase and a solid phase are co-existed) of 130° C.-170° C., more preferably 138° C.-170° C., most preferably 150° C.-170° C. For example, Sn42Bi58-based eutectic solder can be effectively employed. As for this SnBi-based solder, those which is represented by SnₓBi_{y} (wherein x=40 wt %-42 wt %, y=58 wt %-60 wt %) can be also employed. Further, the Sn42Bi58-based eutectic solder to be employed herein may also contain at least one kind of element selected from the group consisting of Ag, Ni, Fe, Ge, Cu and In. For the purpose of enhancing the mechanical characteristics of solder material, the Sn42Bi58-based solder may also contain metallic additives such as Ag, Ni, Fe or Ge (at least one kind thereof, i.e. one to four kinds).

The mixing ratio of the powder of low melting point lead-free solder in the conductive bonding material should preferably be confined within the range of 10 to 90 wt %, more preferably 40 to 80 wt %. In this case, the ratio of flux (epoxy-based adhesive exhibiting fluxing effects, the same hereinafter) would become 90 to 10 wt %, more preferably 60 to 20 wt %. When the mixing ratio of the powder of low melting point lead-free solder is 10 wt % or more, the formation of fillet onto the semiconductor chip components can be effectively performed. Further, when the mixing ratio of the powder of low melting point lead-free solder is not more than 90 wt %, it is possible to secure a sufficient reinforcement of the bonding strength of the semiconductor chip components that have been bonded.

The powder of solder may be spherical or flake-like in configuration. As for the particle diameter of the powder of solder, although there is not any particular limitation, it should preferably be confined to the range of 1 to 100 μm, more preferably 25 to 80 μm, most preferably 30 to 60 μm. Further, the average particle diameter of the powder of solder should preferably be confined to not larger than 50 μm. If the particle diameter of the powder of solder is too small, it would be impossible to achieve satisfactory bonding. On the other hand, if the particle diameter of the powder of solder is too large, the bonding of the fine pitched portion would become insufficient. When the average particle diameter of the powder of solder is confined to not larger than 50 μm, the land may be enabled to give preferable influence to the printability onto the circuit substrate of fine pitches. The particle diameters described above are derived from the measurement by means of laser diffraction method.

If required, the conductive bonding material of the present invention may further contain, in addition to the aforementioned materials, various kinds of additives such as active agents other than those mentioned above, a thixotropic agent, a coupling agent, an antifoaming agent, a powder surface treating agent, a reaction inhibitor, an anti-settling agent, etc. These additives can be uniformly intermingled with the conductive bonding material. The mixing ratio of these additives such as active agents, a thixotropic agent, a coupling agent, an antifoaming agent, a powder surface treating agent, a reaction inhibitor and an anti-settling agent should preferably be confined to the range of 0.01-10 wt %, more preferably 0.05-5 wt % based on the weight of the flux composition (adhesive composition). If the mixing ratio of these additives is less than the aforementioned lower limit, the effects of each of these additives cannot be sufficiently obtained. On the other hand, if the mixing ratio of these additives is larger than the aforementioned upper limit, it would be impossible to realize excellent bonding effects.

When the solder material in the conductive bonding material of the present invention is powdery, the conductive bonding material can be easily manufactured by subjecting the aforementioned essential components to kneading treatment together with the aforementioned additives to be incorporated as required, thus producing a paste-like product. The conductive bonding material thus manufactured can be employed for electrically connecting a conductive ball or a conductive pin with the conductive land or through-hole of a semiconductor packaging substrate (such as a ball grid array (BGA) and a pin grid array (PGA)) by way of the reflow of the conductive bonding material. Additionally, the conductive bonding material can be suitably employed also for the manufacture of modules or for the bonding of various kinds of electronic components. For example, in the case of mounting a semiconductor chip on the conductive land or through-hole of a semiconductor package substrate or in the case of mounting a semiconductor chip on a module of electronic instrument or in the case of mounting a semiconductor chip on a printed wiring board, the conductive bonding material is employed in such a manner that it is delivered by means of syringe or printed by making use of a metal mask to form an adhesive resin layer, to which a conductive ball or a conductive pin is bonded or adhered, thereby making it possible, due to the tackiness of the adhesive resin layer, to prevent the conductive ball or the conductive pin from falling off. The semiconductor chip components are mounted on the conductive ball or the conductive pin and then the low melting point solder is heated and fused for bonding the semiconductor chip components. On this occasion, the solder in the conductive bonding material is fused and separated from the fluxing component (adhesive component which is constituted by components other than the solder, such as resin), thereby enabling the solder to wet the metal to be soldered, thus accomplishing the soldering. On the other hand, the adhesive is enabled to form a resin film and then to initiate the curing thereof due to the heating applied thereto concurrent with the fusion of the solder, the curing of the adhesive being substantially accomplished after the accomplishment of the soldering, thus accomplishing the flux (adhesive)-bonding of the soldered portion. When the curing of the adhesive is accelerated before the fusion of the powder of solder, the solderability (soldering strength) of soldered portion would be deteriorated, allowing the formation of a large number of solder balls in the cured material. On the occasion of performing the soldering and curing by making use of the conductive bonding material according to the present invention, the temperature to be employed for the heating is generally set to 150-180° C., preferably 150-170° C.

On this occasion, as described hereinafter with reference to the following Example 1, the heating rate is set to 1.8° C. or more per second (≧1.8° C./sec.) so as to enable the solder to fuse prior to the curing of the fluxing component (adhesive component) in the course of linear increase of temperature in the reflow profile indicating a temperature fluctuation history due to heating as shown in FIG. 2 for example. As a result, it is now possible to easily control the temperature control and to bring the solder into a fused state quickly, thereby making it possible to achieve the electric connection and soldering. Due to the curing of the fluxing component (adhesive component) that is effected subsequently, it is possible to suitably perform the bonding of the conductive ball or the conductive pin as well as the bonding of semiconductor components.

In this manner, it is possible to obtain a conductive ball or pin-mounted semiconductor packaging substrate wherein a conductive ball or a conductive pin is mounted on a conductive land or through-hole of the semiconductor packaging substrate by making use of a conductive bonding material, and to obtain an electronic component module wherein a semiconductor chip component is bonded to a chip-mounting substrate by making use of a conductive bonding material. For example, it is possible to obtain an electronic module wherein an electrode formed on the underside of QFN or ball bumpless LGA is soldered or bonded to a chip-mounting substrate by means of a conductive bonding material. Even if a printed wiring substrate is employed in place of the chip-mounting substrate, it is possible to obtain a printed wiring substrate wherein a semiconductor chip component is soldered or bonded thereto by making use of a conductive bonding material.

In contrast to the conventional complicated process wherein a Ag-based conductive adhesive is employed for the bonding, a sealing agent is employed for the fixing and an underfill is employed for the reinforcement, it is now possible, through the employment of the conductive bonding material of the present invention, to greatly enhance the bonding strength as compared with the bonding strength that can be obtained through the employment of conventional solder paste or adhesive and to greatly reduce the number of steps required for the bonding. Moreover, since a silver-based solder material is no longer employed in the present invention, it is possible to obviate any possibility of generating the migration of silver even in electric components provided with a tin-plated electrode and to reduce the manufacturing cost. Further, since electronic components can be mounted on a substrate without necessitating the high-temperature reflow of lead-free solder, even the electronic components which are inferior in heat resistance can be efficiently mounted on a substrate.

An SnBi-based conductive bonding material consisted of a mixture comprising powdery SnBi-based low melting point solder and a solvent-free type flux composition (adhesive composition) comprising epoxy resin, a curing agent (cure promoter) and dibasic acid having alkyl group on its side chain is featured in that it is useful in securing the electric conductivity for the connection of circuit through the bonding by means of a low melting point solder, and that it is useful in reinforcing the adhesive strength of soldered components due to the effects of the adhesive, thereby overcoming, en bloc, the problems of aforementioned electric conductivity and reinforcement of adhesive strength. Further, this conductive bonding material is provided with repairing property. Therefore, this conductive bonding material may be defined as having not only the advantages of the conventional non-fusion type conductive adhesive but also the advantages of the conventional solder paste, wherein these advantages are further developed.

As described above, since it is possible, with this conductive bonding material, to secure enhanced bonding strength which the conventional conductive bonding material has failed to achieve, this conductive bonding material is excellent in practical application for use in the bonding by way of simple reflow profile, thus enabling it to exhibit high reliability in the process of heating/cooling cycle or repeated reflow.

According to the present invention, it is possible, due to the tackiness of the thermosetting adhesive resin provided with fluxing effects, to prevent a conductive ball or a conductive pin from falling from the conductive land or through-hole of semiconductor packaging substrate, and to dispense with washing treatment since there is no possibility of leaving residual film as seen in the case of the ordinary flux. Further, according to the present invention, the soldering by way of reflow for mounting a conductive ball or a conductive pin on a semiconductor package substrate can be performed at a low temperature of as low as 160° C. and, moreover, it is now possible, according to the present invention, to achieve, en bloc, the enhancement of electric conductivity of the connected portion between circuits by the effects of soldering and the enhancement of adhesive strength by the effects of flux (adhesive), thereby making it possible to reduce the number of steps required for the bonding. Furthermore, since application of pressure is not needed in this reflow soldering, any redundant stress would no longer be imposed on the semiconductor package or on the soldered portion, thus preventing the products from being damaged in reliability.

### BRIEF DESCRIPTION OF THE SEVERAL VIEWS OF THE DRAWING

FIG. 1 is a cross-sectional view illustrating a semiconductor package substrate mounted with solder balls;

FIG. 2 is a graph showing reflow profiles obtained through the employment of the conductive bonding material of one example of the present invention and the employment of a lead-free solder paste of comparative example;

FIG. 3 shows photographs wherein (a) and (b) respectively shows an upper slant view of the solder ball-mounted substrate that has been treated under varied reflow conditions by making use of the conductive bonding material of one example of the present invention; and (c) shows an upper slant view of the solder ball-mounted substrate that has been reflow-treated by making use of the flux of comparative example;

FIG. 4 shows enlarged photographs of ×100, ×180, ×500 and ×5000, each illustrating the cross-sectional view of the ball-mounted portion shown in each of the photographs of (a) and (b) of FIG. 3.

### DETAILED DESCRIPTION OF THE INVENTION

Next, the present invention will be explained specifically with reference to the following examples and comparative examples, which are not intended to limit the present invention in any manner. In the following description, “part(s)” means “weight part(s)”.

### Example 1

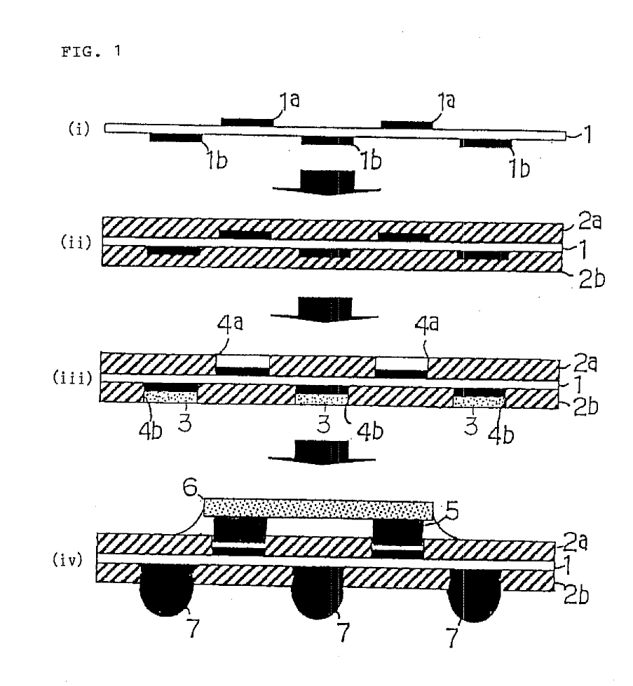

As shown in FIG. 1 for example, in the step of (i), a circuit wiring 1a is formed on one surface of a circuit substrate 1 having a conductive pattern formed thereon and another circuit wiring 1b is formed on the other surface thereof. In the step of (ii), a solder resist composition is coated on both surfaces and cured to form cured coat films 2a and 2b. Then, in the step of (iii), laser beam is irradiated to these coat films to form via-holes 4a and 4b. In the step (iv), either gold plating is applied to the circuit wiring 1a or the circuit wiring 1a is subjected to preflux treatment and then a semiconductor chip 6 is bonded, via a gold bump or a solder bump 5 attached to the underside of the semiconductor chip 6, to the circuit wiring 1a. Alternatively, in the step (iv)′ to be performed in place of the step (iv), the same kind of bump as the bump 5 is formed on the circuit wiring 1a and the circuit wiring 1a is bonded, via this bump, to the electrodes formed on the underside of the semiconductor chip 6. Thereafter, subsequent to the step of (iv) or (iv)′, bumps 7 are formed on the opposite side of the circuit substrate (the step (iv)′ is not shown).

On this occasion, the same kind of bump as the bump 5 can be formed on the circuit wiring 1a in such a manner that a solder paste is coated on the circuit wiring 1a, then heated to fuse by way of reflow and cooled to solidify. For the formation of the bump 7, the following conductive bonding material is either delivered onto the circuit wiring 1b by making use of a syringe or printed by making use of a metal mask, thereby forming a conductive bonding material film 3 (FIG. 1(iii)).

(Conductive Bonding Material)

18.6 parts of bisphenol A epoxy resin (trade name, Epicoat 828; Japan Epoxy Resin Co., Ltd.), 1.2 parts of 2P4MZ (trade name, curing agent available from Shikoku Kasei Industries Ltd.), and 2.2 parts of 2,4-diethylgultaric acid were mixed together by means of homogenizer to manufacture a flux (epoxy adhesive exhibiting fluxing effects). 22 parts of this flux and 78 parts of solder powder (20-40 μm in particle diameter) consisting of Sn42Bi58 (the number denotes wt %, the same hereinafter) were mixed together for three hours by making use of a planetary mixer to manufacture a non-solvent type paste-like conductive bonding material. Table 1 shows the composition thereof.

Then, a solder ball or a solder pin (a solder ball in the case of FIG. 1) was placed, as a conductive ball or a conductive pin, on the conductive bonding material film 3 and subjected to reflow treatment.

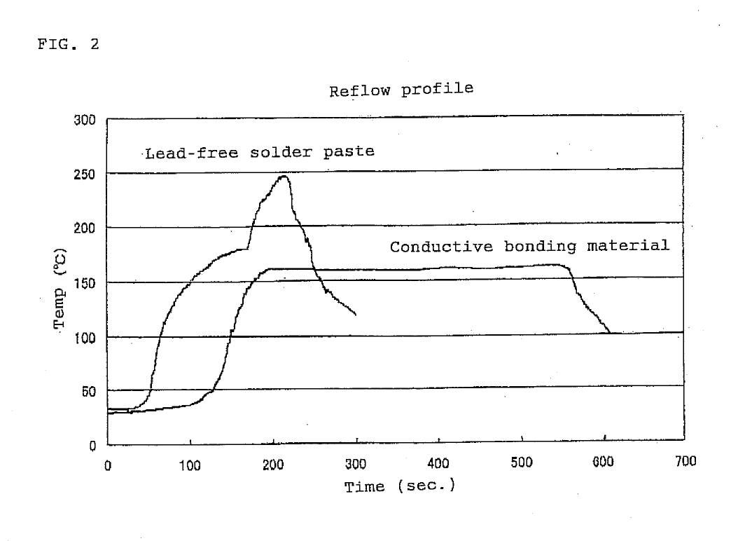

The reflow treatment was performed by setting and heating a test piece in the same manner as in the case of the paragraph “(3) BGA ball bonding strength”, whereby the conductive ball or the conductive pin was treated at temperatures according to the reflow profile shown by a solid line of “conductive bonding material” shown in FIG. 2, thereby enabling the solder powder to fuse at the approximately linear rising portion thereof. After the fusion of the solder powder, the resin component in the flux was cured at the flat portion (about 106° C.) of temperature, thus accomplishing the curing. This accomplishment of the curing was confirmed from the hardness of flux film.

In this manner, it was possible to obtain a semiconductor package substrate (solder ball-mounted semiconductor substrate) provided with bumps 7 of solder ball which were mounted thereon through the reflow bonding of conductive bonding material. This solder ball-mounted semiconductor package substrate can be mounted on a mother board through the bonding by way of the fusion of the bumps 7.

Although not shown in the drawings, the circuit substrate 1 having a conductive circuit pattern formed thereon was provided with through-holes, through which the circuit wirings 1a and 1b were connected with each other via a plated film formed on the inner wall of the through-holes.

### Example 2

A non-solvent type paste-like conductive adhesive was prepared in the same manner as in Example 1 except that 2,5-diethyladipic acid was substituted for 2,4-diethylgultaric acid in the flux composition as shown in the column of Example 2 of Table 1. Then, a solder ball-mounted semiconductor package substrate was manufactured in the same manner as described in Example 1 except that this non-solvent type conductive bonding material was employed.

### Comparative Examples 1 and 2

An Sn42Bi58-based solder paste (Comparative Example 1) was prepared by kneading a mixture comprising 10 parts of lead-free flux (rosin-based lead-free flux formed of a mixture comprising 50 parts of hydrogenated rosin, 4 parts of gultaric acid, 8 parts of thixotropic agent and 38 parts of butyldiglycol), and 90 parts of solder powder (20-40 μm in particle diameter) consisting of Sn42Bi58. Further, the aforementioned rosin-based lead-free flux (Comparative Example 2) was separately prepared. Then, solder ball-mounted semiconductor package substrates were manufactured in the same manner as described in Example 1 except that these solder paste and flux were substituted for the conductive bonding material of Example 1. The compositions thereof are shown in Table 1.

When the solder paste of Comparative Example 1 and the flux of Comparative Example 2 were employed in place of the conductive bonding material of Example 1, it was possible to confirm that they could be treated at temperatures according to the reflow profile shown by a solid line of “lead-free solder paste” shown in FIG. 2 and that they could not be completely fused unless the solder was caused to pass over the peak of temperature rise.

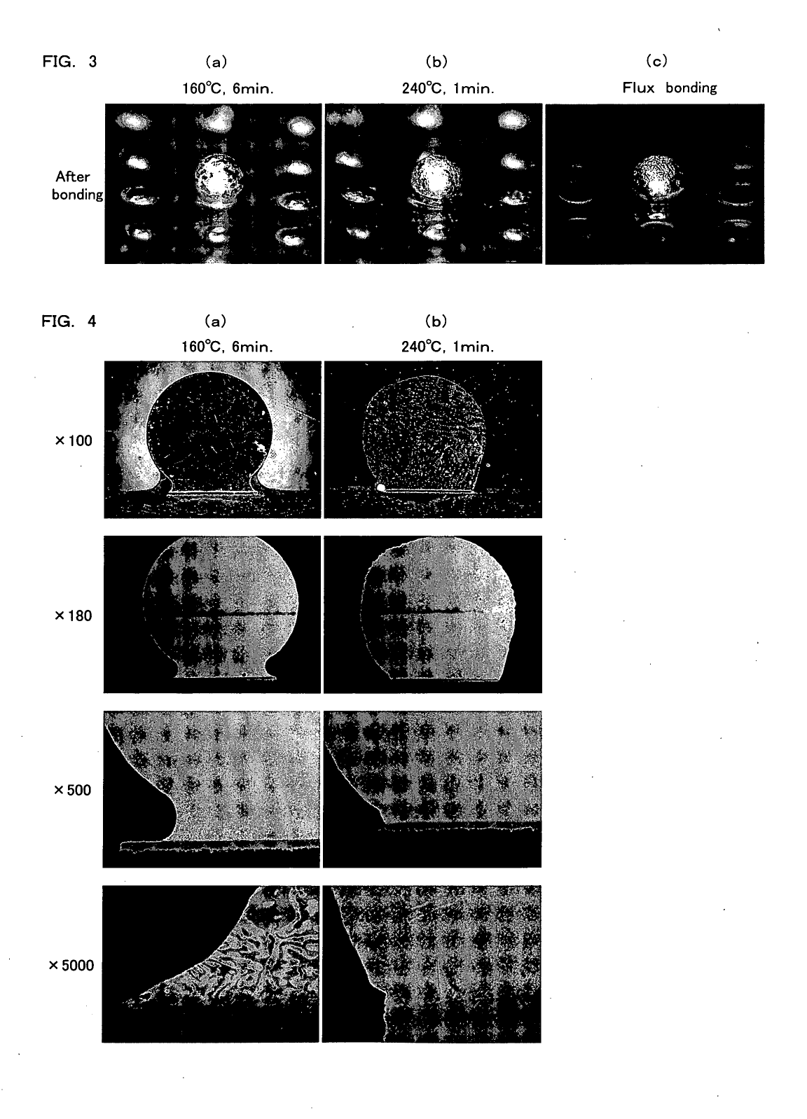

The conductive bonding materials obtained from Examples, the solder paste obtained from Comparative Example 1 and the flux obtained from Comparative Example 2 were subjected to the assessments and test of the following items (1) to (3). The results obtained are shown in Table 2, and FIGS. 3 and 4.

(1) Assessment on tackiness:

In order to assess the holding power (falling resistance) of the solder ball, the aforementioned conductive bonding materials, the solder paste and the flux were assessed with respect to the tackiness of the coated layers thereof and compared with each other (based on JIS Z 3284).

(2) Assessment on washing treatment:

“Washing treatment” where a solder paste was employed is marked by “x” (needed); while “Washing treatment” where a conductive bonding material comprising an adhesive resin or an adhesive was employed is marked by “O” (not needed).

(3) Test on BGA ball bonding strength;

To an SP-059A substrate (1.6 mm in thickness)(the substrate 1 of FIG. 1) with a land 0.6 mm in diameter (circuit wiring 1b of FIG. 1), the printing of each of the aforementioned materials (the materials of Examples and Comparative Examples as shown in Table 1) was applied using a metal mask (0.08 mm in thickness). Then, a BGA ball (Sn/3.0Ag/0.5Cu; 760 μm in diameter) was mounted and treated under the reflow conditions of: 160° C./6 minutes; and 240° C./minute. Thereafter, the bonding strength of the ball was measured by making use of a bond tester (SERIEC 4000, Arctech Co., Ltd.). The values shown in Table 2 are respectively an average value obtained from 10 samples.

Further, the state of bonding at the interface between the BGA ball and the land was observed and photographed as shown in FIG. 3. Further, by making use of an optical microscope, the cross-sectional view of the bonded portion was observed and photographed as shown in FIG. 4.

FIGS. 3(a) and 3(b) respectively shows the photographs of the solder ball-mounted substrate wherein it was treated for/minute under the reflow conditions of: 160° C./6 minutes; and 240° C./minute by making use of the conductive bonding material of Example 1; and FIG. 3(c) shows the photograph of the solder ball-mounted substrate wherein it was treated for/minute under the reflow conditions of; 240° C./minute by making use of the flux of Comparative Example 2. FIG. 4 shows enlarged photographs of ×100, ×180, ×500 and ×5000, each illustrating the cross-sectional view of the ball-mounted portion shown in each of the photographs of (a) and (b) of FIG. 3.

TABLE 1

| | | | | | Comp. | Comp. |
|---|---|---|---|---|---|---|
| Items | | | Ex. 1 | Ex. 2 | Ex. 1 | Ex. 2 |
| Composition | Composition | Epoxy resin Epicoat 828 | 18.6 | 18.6 | | |
| of | of flux | Curing agent 2P4MZ | 1.2 | 1.2 | | |
| conductive | | 2,4-diethylgultaric acid | 2.2 | | | |
| bonding | | 2,4-diethyladipic acid | | 2.2 | | |
| | | Lead-free flux | | | 10 | 100 |

| | | | | |
|---|---|---|---|---|
| Solder Sn42Bi58 | 78 | 78 | 90 | — |
| Average particle diameter 20-40 μm | | | | |

TABLE 2

| | | | | Comp. | Comp. |
|---|---|---|---|---|---|
| Items | | Ex. 1 | Ex. 1 | Ex. 1 | Ex. 2 |
| (1) Tackiness | Initial values | 1.2 | 1.4 | 1.1 | 1.5 |
| (N) | immediately | | | | |
| N: Newton | after coating | | | | |
| | After left for | 1.3 | 1.3 | 0.8 | 0.4 |
| | 24 hrs. under | | | | |
| | 25° C. and 50% | | | | |
| | RH after coating | | | | |
| (2) Flux washing | | ◯ | ◯ | X | X |
| ◯: No; X: Yes | | | | | |
| (3) BGA ball | 160° C., 6 min. | 1949 | 1957 | 1429 | — |
| bonding | 240° C., 1 min. | 1593 | 1608 | 1197 | 2374 |
| strength (gf) | | | | | |

It will be recognized from the results shown in Table 2 that, in the cases where the conductive bonding materials of Examples 1 and 2 were employed, it was possible to secure sufficient tackiness and to minimize the changes with time (especially when liquid resin was employed), so that the possibility of generating falling of the BGA ball as it is mounted thereon can be minimized. Whereas in the cases of Comparative Examples 1 and 2, the tackiness was deteriorated within a short period of time, thus increasing the possibility of generating the defectives due to the falling of the BGA ball.

Further, when the reflow treatment was performed using the solder paste of Comparative Example 1 or the flux of Comparative Example 2, it was required to wash the flux. Whereas, when the reflow treatment was performed using the conductive bonding materials of Examples 1 and 2, such washing treatment could be dispensed with.

With respect to “BGA ball bonding strength”, the values obtained from Examples 1 and 2 were found larger than 1000 gf (target value) which level was considered satisfactory as a bonding strength for the ordinary Sn/3.0Ag/0.5Cu ball, thus sufficiently meeting this target value. Moreover, even under the reflow conditions of: 160° C./6 minutes, the BGA ball bonding strength obtained from Examples 1 and 2 was found satisfactory. Further, the photographs of (a) and (b) of FIGS. 3 and 4 (wherein the conductive bonding material of Example 1 was employed and the reflow treatment was performed under the conditions of: 160° C./6 minutes and 240° C./minute), especially the photographs of (a) and (b) of FIG. 4 clearly indicate, as seen from the cross-sectional view of the BGA ball, that the state of bonding at the interface between the BGA ball and the land was satisfactory and free from any problems such as cissing or voids (voids due to air bubbles) of solder as the reflow treatment conditions was set to 160° C./6 minutes or 240° C./minute.

Additionally, another substrate was superimposed on the ball-mounted substrate having the same configuration as those shown in the photographs of (a) and (b) of FIG. 3 and the resultant composite structure was photographed from one side thereof. Thereafter, the substrate thus superimposed (upper substrate) was peeled away from the ball-mounted substrate (lower substrate) and these upper and lower substrates were photographed (the photographs thereof being omitted here), finding that the upper substrate was sufficiently wet with solder, thus indicating satisfactory solder bonding effected between these upper and lower substrates.

Since the conductive bonding material according to the present invention is excellent in conductivity and adhesive properties and suited for low-temperature bonding, it can be used for reliably and efficiently bonding a conductive ball or a conductive pin to a semiconductor packaging substrate by way of reflow. Additionally, the conductive bonding material of the present invention can be also utilized in the mounting of other electronic components on a printed wiring board, etc.

For example, the conductive bonding material of the present invention can be used for mounting various kinds of LSI such as CPU, MPU, etc., electronic components (active elements and passive elements) such as a chip inductor, a chip conductor, etc., and conductive terminals or conductive wiring materials on a printed wiring board (PWB) for the purpose of modularization of various kinds of electronic components. In this mounting process, the conductive bonding material is fused and solidified so as to be electrically connected with the PWB. More specifically, the conductive bonding material of the present invention can be used for the bonding where a strong bonding power such as tensile strength is required as in the case where electronic components are prevented from falling from the PWB and enabled to secure excellent conductivity even if strong mechanical shocks such, for example, as shocks from moving vehicles are given to the conductive bonding material.

What is claimed is:

1. A conductive ball- or pin-mounted semiconductor packaging substrate having a conductive ball or a conductive pin mounted on a conductive land or through-hole of the semiconductor packaging substrate, wherein the conductive ball or the conductive pin is electrically connected with the conductive land or through-hole through the coating and reflow of a conductive bonding material comprising, at least, a conductive material formed of a low-melting point lead-free solder having a melting point of 130-170° C., and a thermosetting adhesive resin exhibiting fluxing effects.

2. The conductive ball- or pin-mounted semiconductor packaging substrate according to claim 1, wherein the low-melting point lead-free solder is formed of a SnBi-based solder, and the thermosetting adhesive resin exhibiting fluxing effects is constituted by a mixture comprising an epoxy resin and a curing agent.

3. The conductive ball- or pin-mounted semiconductor packaging substrate according to claim 2, wherein the epoxy resin is formed of components which are solid and/or liquid at ordinary temperature.

4. The conductive ball- or pin-mounted semiconductor packaging substrate according to claim 2, wherein the thermosetting adhesive resin exhibiting fluxing effects is formed of a mixture comprising an epoxy resin and a curing agent, the mixture further containing 1-10% by weight of dibasic acid having lower alkyl group having 1-5 carbon atoms, and a total number of carbon atom included in the dibasic acid being at least six.

5. The conductive ball- or pin-mounted semiconductor packaging substrate according to claim 3, wherein the thermosetting adhesive resin exhibiting fluxing effects is formed of a mixture comprising an epoxy resin and a curing agent, the mixture further containing 1-10% by weight of dibasic acid having lower alkyl group having 1-5 carbon atoms, and a total number of carbon atom included in the dibasic acid being at least six.

6. The conductive ball- or pin-mounted semiconductor packaging substrate according to claim 2, wherein the low-melting point lead-free SnBi-based solder is contained at a ratio of 10-90% by weight, and the thermosetting adhesive resin exhibiting fluxing effects is contained at a ratio of 90-10% by weight.

7. The conductive ball- or pin-mounted semiconductor packaging substrate according to claim 5, wherein the low-melting point lead-free SnBi-based solder is contained at a ratio of 10-90% by weight, and the thermosetting adhesive resin exhibiting fluxing effects is contained at a ratio of 90-10% by weight.

8. A conductive bonding material which is described in claim 1.

9. A conductive bonding material which is described in claim 2.

10. A conductive bonding material which is described in claim 5.

11. A conductive bonding material which is described in claim 6.

12. A conductive bonding material which is described in claim 7.

13. A method of manufacturing a conductive ball- or pin-mounted semiconductor packaging substrate having a conductive ball or a conductive pin mounted on a conductive land or through-hole of the semiconductor packaging substrate, the method comprising the steps of: forming a conductive bonding material layer by applying a conductive bonding material comprising, at least, a low-melting point lead-free SnBi-based solder and a thermosetting adhesive resin exhibiting fluxing effects to the conductive land or through-hole; and causing the conductive bonding material to reflow to thereby electrically connect the conductive ball or the conductive pin with the conductive land or through-hole.

14. The manufacturing method according to claim 13, wherein the conductive bonding material claimed in claim 9 is employed as a conductive bonding material containing the thermosetting adhesive resin exhibiting fluxing effects.

15. The manufacturing method according to claim 13, wherein the conductive bonding material claimed in claim 10 is employed as a conductive bonding material containing the thermosetting adhesive resin exhibiting fluxing effects.

16. The manufacturing method according to claim 13, wherein the conductive bonding material claimed in claim 11 is employed as a conductive bonding material containing the thermosetting adhesive resin exhibiting fluxing effects.

17. The manufacturing method according to claim 13, wherein the conductive bonding material claimed in claim 12 is employed as a conductive bonding material containing the thermosetting adhesive resin exhibiting fluxing effects.

18. The manufacturing method according to claim 13, wherein the low-melting point lead-free SnBi-based solder is caused to fuse prior to the curing of the thermosetting adhesive resin exhibiting fluxing effects.

19. The manufacturing method according to claim 16, wherein the low-melting point lead-free SnBi-based solder is caused to fuse prior to the curing of the thermosetting adhesive resin exhibiting fluxing effects.

20. The manufacturing method according to claim 17, wherein the low-melting point lead-free SnBi-based solder is caused to fuse prior to the curing of the thermosetting adhesive resin exhibiting fluxing effects.
